(19) United States
(12) Patent Application Publication
(10) Pub. No.: US 2002/0056849 A1
(43) Pub. Date: May 16, 2002

(54) Submount having transmission line and method for forming

(76) Inventors: Dan A. Steinberg, Blacksburg, VA (US); David W. Sherrer, Blacksburg, VA (US)

Correspondence Address: HALEOS, INC., 3150 STATE STREET, BLACKSBURG, VA, 24060, US

(21) Appl. No.: 09/987,139

(22) Filed: Nov. 13, 2001

Related U.S. Application Data
(60) Provisional application No. 60/249,567, filed on Nov. 16, 2000.

(51) Int. Cl. H01L 33/00

(52) U.S. Cl. 257/98

(57) ABSTRACT

A submount and a method for making the submount, is described. A substrate has a channel formed therein. An insulator material, such as a dielectric material, is deposited on the substrate within the channel and on an upper surface of the substrate. A conductive material is deposited over the dielectric material. Preferably, the conductive material within the boundaries of the channel should be lower than the upper surface. The substrate is then planarized, which eliminates the conductive material and the dielectric material from outside the boundaries of the channel. Alternatively, an electric ground plate can be formed by doping a region of the substrate surrounding the channel or by depositing a second conductive material prior to laying down the dielectric material. Optionally, a second dielectric material may be positioned over the conductive material, and after planarization a conductive material may be deposited and patterned thereon.

### CROSS-REFERENCE TO RELATED APPLICATIONS

This application claims priority from provisional application serial No. 60/249,567, filed Nov. 16, 2000, the entire disclosure of which is incorporated herein by reference.

### FIELD OF THE INVENTION

The invention generally relates to a substrate having a transmission line formed therein, and a method of making the transmission line. The transmission line can be very small

### BACKGROUND

Semiconductor modules for use with semiconductor devices are known. One conventional method for forming such a module may be found in U.S. Pat. No. 5,412,748 (Furuyama et al.).

### SUMMARY

The invention provides a submount with a transmission line within a channel. The submount includes a substrate with a channel having boundaries, a layer of insulator material within the boundaries of the channel, and a conductive material deposited on the insulator material and within the boundaries of the channel, wherein the conductive material extends below the upper surface.

The invention also provides a semiconductor module that includes a semiconductor device and a submount with a transmission line within a channel. The submount includes a substrate with a channel having boundaries, a layer of insulator material within the boundaries of the channel, and a conductive material deposited on the insulator material and within the boundaries of the channel.

The invention further provides a method for forming a submount. The method includes preparing a channel in a substrate, the channel being defined by an upper surface, positioning an insulator material within the channel, depositing a conductive material on the insulator material, and planarizing the substrate.

These and other advantages and features of the invention will be more readily understood from the following detailed description of the invention which is provided in connection with the accompanying drawings.

### BRIEF DESCRIPTION OF THE DRAWINGS

FIGS. 1-4 are cross-sectional views showing the construction of a submount in accordance with an embodiment of the invention.

FIGS. 5-6 are cross-sectional views showing the construction of a submount in accordance with another embodiment of the invention.

FIG. 7 is a top view of a submount constructed in accordance with another embodiment of the invention.

FIG. 8 is a cross-sectional view taken along line VIII-VIII of FIG. 7.

FIG. 9 is a cross-sectional view taken along line IX-IX of FIG. 7.

FIG. 10 is a top view of a submount constructed in accordance with another embodiment of the invention.

FIG. 11 is a cross-sectional view of a semiconductor module constructed in accordance with another embodiment of the invention.

FIG. 12 is a cross-sectional view of a semiconductor module constructed in accordance with another embodiment of the invention.

FIGS. 13-17 are cross-sectional views showing the construction of a submount in accordance with an embodiment of the invention.

FIG. 18 illustrates steps for forming a submount in accordance with an embodiment of the invention.

FIG. 19 illustrates steps for forming a submount in accordance with another embodiment of the invention.

### DETAILED DESCRIPTION OF PREFERRED EMBODIMENTS

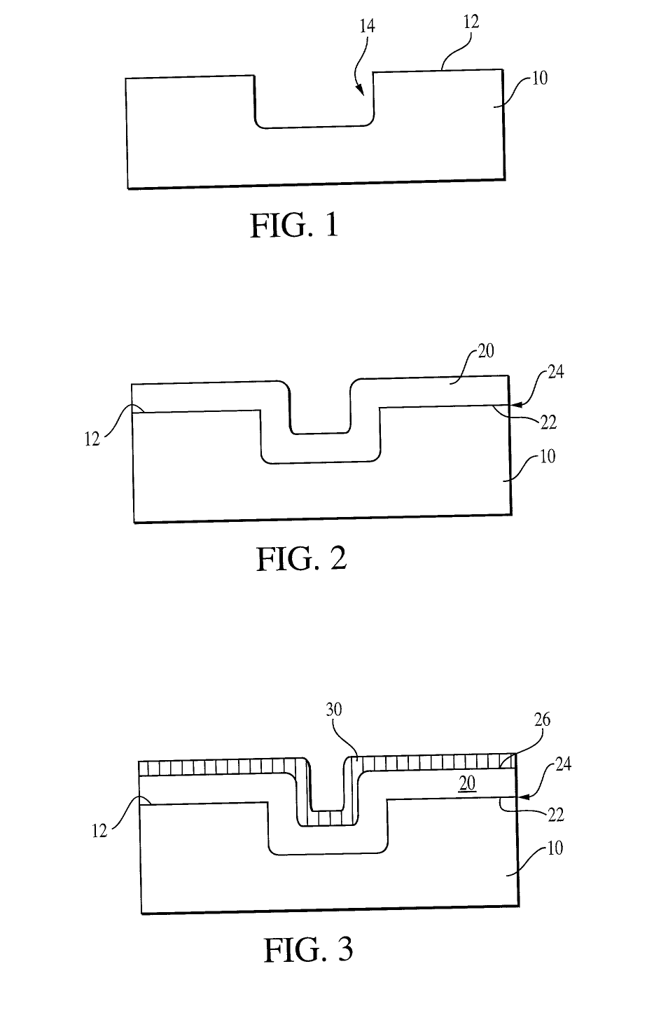

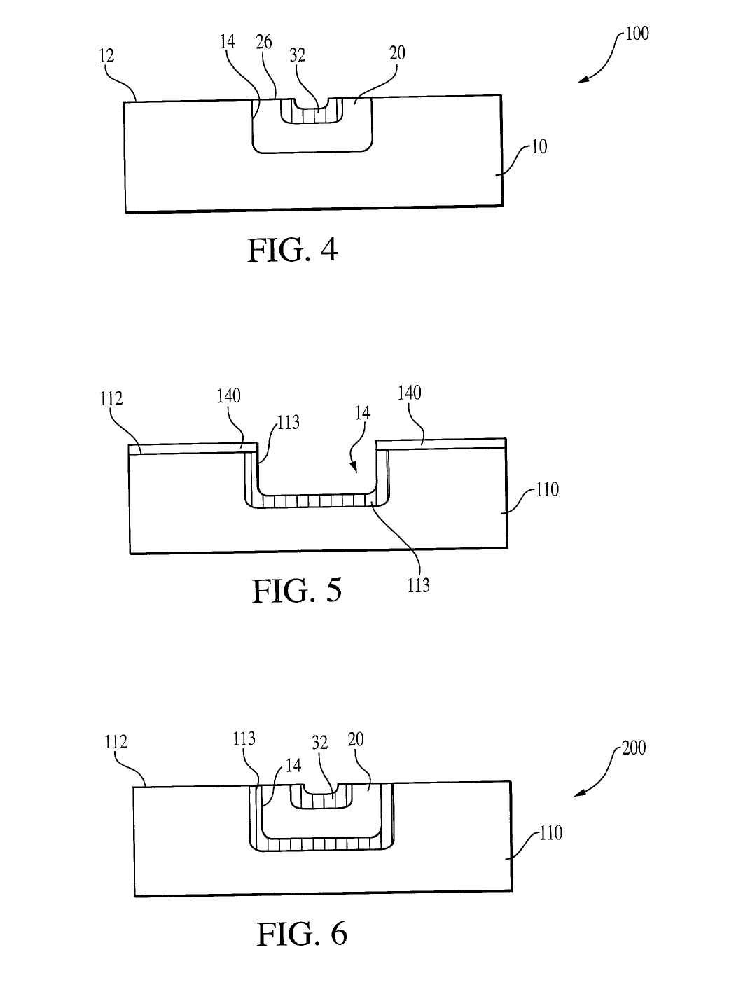

Referring now to FIGS. 1-4, there is illustrated a submount 100 (FIG. 4) in various stages of formation. Specifically, in FIG. 1 a substrate 10 is shown with a channel 14 having been prepared in an upper surface 12. The substrate 10 may be formed of an etchable or moldable material, such as, for example, silicon, glass, ceramic, metal or polymer. The channel 14 may be formed by isotropic wet etching, reactive ion etching, anisotropic wet etching, or the like. Additionally, gray scale lithography may be used to form the channel 14 into a particular shape.

FIG. 2 illustrates the coating of an insulator material 20 on the upper surface 12 of the substrate 10. The insulator material 20 conformally coats the upper surface 12 and the channel 14 of the substrate 10. Preferably, the insulator material 20 is a dielectric material, such as silicon nitride or silicon dioxide, and it is formed by, for example, chemical vapor deposition or thermal oxidation. A lower surface 22 of the insulator material 20 and the upper surface 12 of the substrate 10 form an insulator/substrate boundary 24. As noted above, the substrate 10 may be formed of a conductive material, such as metal or doped silicon, or it may have a conductive coating. If a metallic substrate 10 is used, then the substrate 10 may serve as a ground plane.

FIG. 3 illustrates the deposition of a conductive material 30 over the insulator material 20. Although the insulator material 20 is shown as being much thicker than the conductive material 30, it should be understood that a thin layer of the dielectric material 20 may instead be deposited. The conductive material 30 conforms with an upper surface 26 of the insulator material 20. The thickness of the insulator material 20 may be such as to allow a portion of the conductive material 30 within the boundaries of the channel 14 to extend below the insulator/substrate boundary 24. Optionally, however, the top of the conductive material 30 does not extend below the insulator/substrate boundary 24. The conductive material 30 is preferably a metallic material used for electrical connections on circuit chip surfaces, and may be aluminum, copper, chromium, gold, titanium, doped polysilicon, or any other like conductive material, and/or any combinations thereof.

As can be observed in a comparison between FIG. 3 and FIG. 4, portions of the conductive material 30 and the insulator material 20 have been removed from the substrate 10. Specifically, the submount 100 is planarized to remove the portions of the conductive material 30 and the insulator material 20 positioned outside of the boundaries of the channel 14, leaving a transmission line 32 in the upper surface 26 of the insulator material 20. As illustrated in FIG. 4, the submount 100 is planarized down to approximately the insulator/substrate boundary 24. Optionally, some of the insulator material 20 may remain on the substrate 10 after planarization. The boundary 24 can provide an easily recognized stop point for the planarization step (e.g., if the insulator is silicon dioxide and the substrate is silicon).

An alternative embodiment of the invention is illustrated in FIGS. 5-6. Shown in FIG. 5 is a substrate 110, having an upper surface 112, in which a channel 14 is prepared. A region 113 of the substrate 110 surrounding the channel 14 is doped or metalized, thus allowing the region 113 to serve as an electrical ground plane. The doped region 113 can be doped without doping the remainder of the substrate 110 by placing a diffusion mask 140 over the upper surface 112 but not within the channel 14 and depositing dopant materials, or through a vapor deposition process, ion implantation or other suitable doping process. The diffusion mask 140 may be the same mask used to define the boundaries of the channel 14. An insulator material 20 and a conductive material 30 are deposited on the substrate 110 in a manner as described with reference to FIGS. 2-3.

As shown in FIG. 6, the substrate 110 is planarized to form a submount 200 having a transmission line 32 surrounded by an insulator material 20 within the boundaries of a channel 14. A doped region 113 surrounds the insulator material 20 and defines the boundaries of the channel 14. In cases where the substrate 110 is doped and does not include a metallic layer, the insulator material 20 may be deposited through a high temperature process, such as, for example, CVD silicon nitride or CVD silicon dioxide. Alternatively, a thin dielectric layer may be deposited in the channel 14, followed by a deposition of a metal layer, the insulator material 20 and the conductive material 30.

Optionally, a metallic layer may be deposited around the insulator material 20 to define the boundaries of the channel 14.

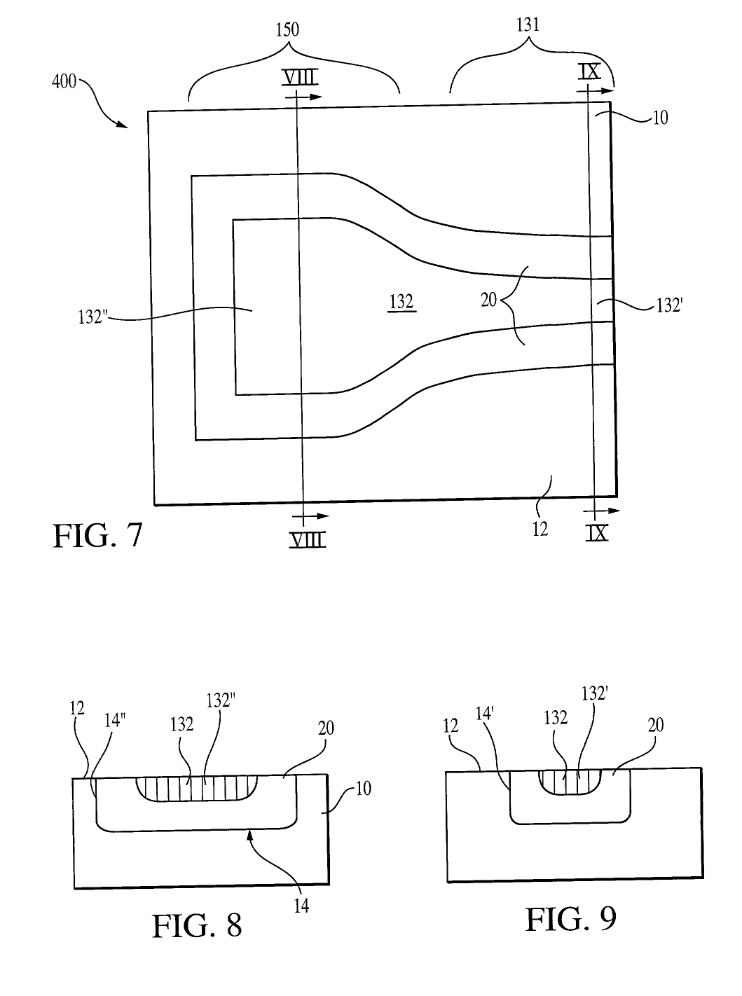

FIGS. 7-9 illustrate another embodiment, namely showing a submount 400 which includes a transmission line area 131 integrally formed with a solder pad area 150. The channel 14 formed in the substrate 10 has a changing profile from a thin profile 14′ (FIG. 9) to a wide profile 14″ (FIG. 8). After formation of the channel 14, the insulator material 20 is conformally coated onto the upper surface 12. Then, a conductive material is deposited on the insulator material 20. Planarization of the submount 400 removes the insulator material 20 and the conductive material exterior to the boundaries of the channel 14, leaving a transmission line 132. The transmission line 132 includes a line section 132′ integrally formed with a solder pad section 132″.

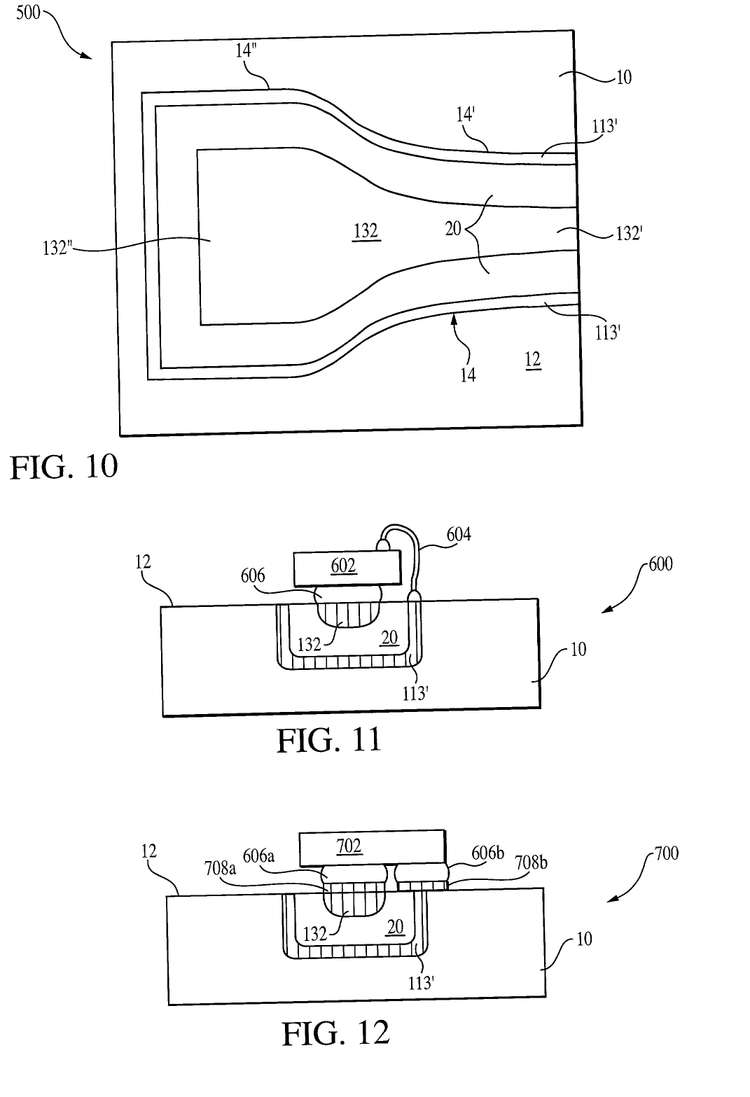

FIG. 10 illustrates an alternative submount 500. As with the submount 400 (FIGS. 7-9), the submount 500 includes a channel 14 with a changing profile from the thin profile 14′ to the wide profile 14″. Then a first conductive material 113′ is located on the upper surface 12 of the substrate 10, including within the channel 14, followed by deposition of the insulator material 20 and a second conductive material, which is a precursor to a transmission line 132. The first conductive material 113′ may be a doped region or may be a deposited metal. Planarization of the submount 500 removes the first conductive material 113′, the insulator material 20 and the second conductive material from outside the boundaries of the channel 14. This leaves the transmission line 132, with the line section 132′ and the solder pad section 132″ surrounded by the insulator material 20 and the first conductive material 113′ within the boundaries of the channel 14.

FIG. 11 illustrates a semiconductor module 600 which includes a semiconductor device 602 mounted on a submount which includes a substrate 10, a first conductive material 113′, and a transmission line 132. The submount may be formed as described with reference to FIGS. 6 and 10. The semiconductor device 602, which may be a laser chip or other optical device, is mounted and electrically connected with the transmission line 132 via a conductive intermediary material, such as, for example, solder. The semiconductor device 602 is further connected to the first conductive material 113′, which acts as an electrical ground plane, with a bond 604, such as, for example, a wire bond.

FIG. 12 illustrates an alternative semiconductor module 700 which includes a semiconductor device 702 mounted on an upper surface 12 of a substrate 10. In this embodiment, a conductive pad 708a is patterned on the transmission line 132 and a conductive pad 708b is patterned on the first conductive material 113′. The semiconductor device 702, which may be a laser chip, is electrically connected with the pad 708a via solder 606a and with the pad 708b via solder 606b. The pads 708a, 708b may be electroplated, electroformed or deposited as a patterned thin film.

Transmission lines 32, 132 may be very small. For example, the solder pad section 132″ may be less than one millimeter in width. Additionally, the transmission lines 32, 132 of the invention may be fabricated to have a certain impedance.

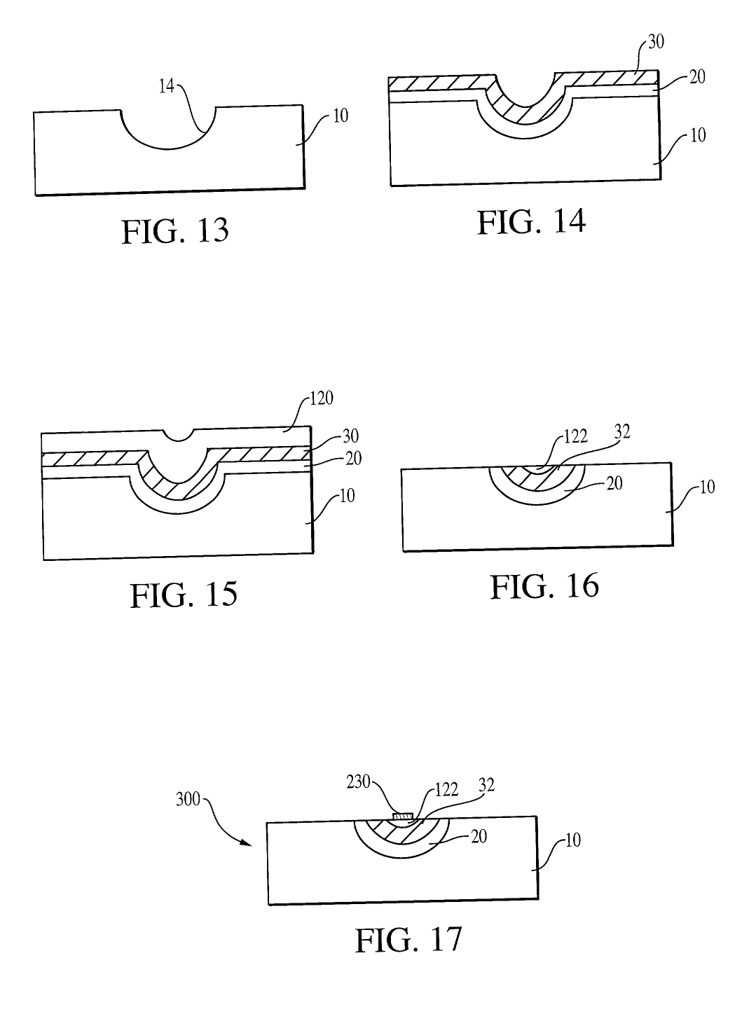

FIGS. 13-17 illustrate the formation of a submount 300 (FIG. 17). Initially, a channel 14 is prepared in a substrate 10 (FIG. 13). Then, as shown in FIG. 14, a conductive material 30 is deposited over the substrate 10. Optionally, and as also shown in FIG. 14, an insulator material 20 may first be deposited on the substrate 10, followed by deposition of the conductive material 30. Then, as shown in FIG. 15, a second insulator material 120 is deposited over the conductive layer 30. The insulator material 120 may be formed at low temperature, such as, for example, glass or a polymer like parylene, polyimide, or other polymers which are capable of being coated, or sputtered glass or ceramics. The substrate 10 is then planarized such that all of the insulator material 20 and 120 outside the boundaries of the channel 14 is removed (FIG. 16), leaving a transmission line 32 and an insulation island 122. Finally, as shown in FIG. 17, a second conductive material 230 may be deposited and patterned on the insulation island 122.

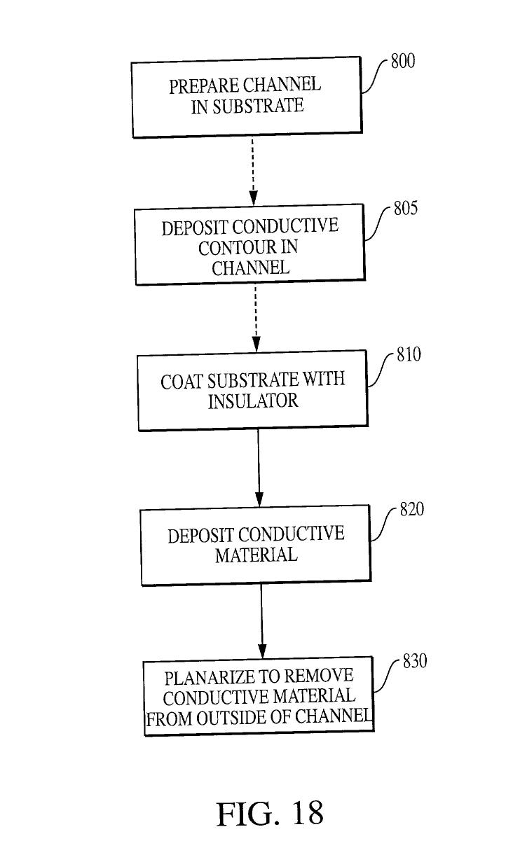

FIG. 18 illustrates steps for forming a submount. As an initial step 800, a substrate is prepared, including forming a channel therein. Subsequent to the initial step, the substrate is coated with an insulator material at step 810. Step 810 may be preceded in some embodiments with a step 805, at which a conductive region may be formed in the channel. The conductive contour defining the channel may be a doped region around the channel or a deposited metalic layer. The doped region may be formed by covering an upper surface of the substrate with a diffusion mask, leaving open the channel and exposing it to dopant materials through a deposition process, such as, for example, plasma deposition, or through an ion implantation process, or by way of another suitable doping process. Alternatively, a conductive layer instead may be deposited in the channel. The doped region or the deposited conductive layer function as an electrical ground plane. After step 810, a conductive material is deposited over the insulator material at step 820. Finally, at step 830, the submount is planarized to remove metal from outside the boundaries of the channel.

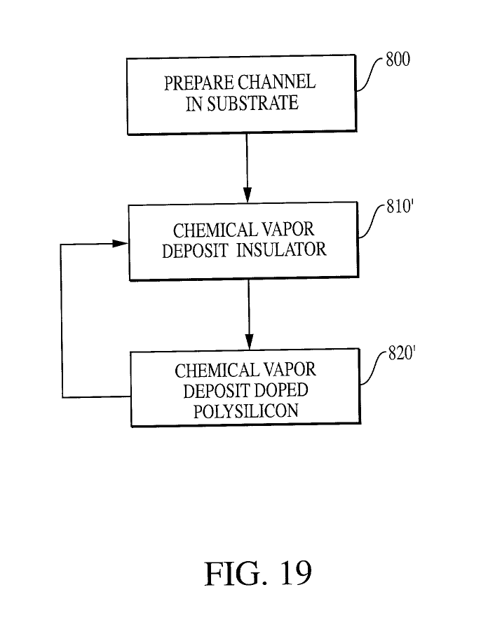

FIG. 19 illustrates steps for forming the entire submount structure within a chemical vapor deposition chamber. The first step, step 800, is to prepare a channel in a substrate. Having prepared the channel, the substrate may be placed within a chemical vapor deposition chamber for a deposition of insulator material at step 810′. Then, a doped polysilicon is deposited on the insulator material at step 820′. The next step is a second chemical vapor deposition of insulator material, which is followed by a repeated deposition of doped polysilicon.

While the invention has been described in detail in connection with exemplary embodiments known at the time, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Accordingly, the invention is not to be seen as limited by the foregoing description, but is only limited by the scope of the appended claims.

What is claimed as new and desired to be protected by Letters Patent of the United States is:

1. A submount with a transmission line within a channel, comprising:
a substrate with an upper surface and a channel having boundaries;
a layer of insulator material within said boundaries of said channel; and
a conductive material deposited on said insulator material and within said boundaries of said channel, wherein said conductive material intersects with and extends below said upper surface.

2. The submount of claim 1, further comprising a doped region of said substrate within said channel.

3. The submount of claim 2, further comprising a second conductive material disposed over said insulator material.

4. The submount of claim 3, further comprising a second layer of insulator material, wherein said second conductive material is deposited on said second layer of insulator material.

5. The submount of claim 1, wherein said conductive material comprises first and second sections, said first section forming a transmission line and said second section forming a solder pad, said transmission line and solder pad being formed integrally within one another.

6. A semiconductor module, comprising:
a semiconductor device; and
a submount with a transmission line within a channel, including:
a substrate with an upper surface and a channel having boundaries;
a layer of insulator material within said boundaries of said channel; and
a conductive material deposited on said insulator material and within said boundaries of said channel, wherein said conductive material intersects with and extends below said upper surface.

7. The semiconductor module of claim 6, wherein said semiconductor device comprises an optical device.

8. The semiconductor module of claim 6, wherein said semiconductor device is electrically connected to said conductive material.

9. The semiconductor module of claim 8, wherein said submount further includes a doped region of said substrate immediately surrounding said boundaries of said channel.

10. The semiconductor module of claim 9, wherein said semiconductor device is electrically connected to said doped region.

11. The semiconductor module of claim 10, further comprising conductive pads for electrically connecting said semiconductor device to said conductive material and said doped region.

12. The semiconductor module of claim 8, wherein said submount further includes a second conductive material.

13. The semiconductor module of claim 12, wherein said submount further includes a second layer of insulator material, said second conductive material being deposited on said layer of insulator material.

14. The semiconductor module of claim 12, wherein said semiconductor device is electrically connected to said second conductive material.

15. The semiconductor module of claim 14, further comprising conductive pads for electrically connecting said semiconductor device to said conductive material and said second conductive material.

16. The semiconductor module of claim 6, wherein said conductive material comprises first and second sections, said first section forming a transmission line and said second section forming a solder pad, said transmission line and solder pad being formed integrally with one another.

17. A method for forming a submount, comprising:
preparing a channel in a substrate, said channel being defined by an upper surface;
positioning an insulator material within said channel;
depositing a conductive material on said insulator material; and
planarizing said substrate to provide a planarized surface, wherein said conductive material intersects with and extends below said planarized surface.

18. The method of claim 17, wherein the planarized surface is below a boundary between the conductive material and the insulator material in an area outside of the channel.q

19. The method of claim 17, further including doping a region of said substrate immediately surrounding said channel prior to said positioning of said insulator material.

20. The method of claim 19, wherein said doping comprises:
placing a diffusion mask on said upper surface; and
depositing a dopant material in said channel.

21. The method of claim 17, further including depositing a second conductive material on said substrate prior to said positioning of said insulator material.

22. The method of claim 17, wherein said planarizing comprises chemical mechanical polishing.

23. The method of claim 17, wherein said preparing of said channel comprises forming a changing profile of said channel, said channel having a profile which changes from a wide profile to a thin profile.

24. The method of claim 23, wherein said depositing of said conductive material comprises depositing said conductive material in first and second sections, said first section corresponding to said thin profile and forming a transmission line and said second section corresponding to said wide profile and forming a solder pad, said transmission line and solder pad being formed integrally within one another.

25. The method of claim 17, further comprising depositing a second insulator material over said conductive material prior to said planarizing.

26. The method of claim 25, further comprising depositing a second conductive material after said planarizing.

27. The method of claim 26, wherein said second conductive material is patterned.
